(19) United States
(12) Patent Application Publication
(10) Pub. No.: US 2023/0253129 A1
(43) Pub. Date: Aug. 10, 2023

(54) METHOD FOR PRODUCING REFLECTIVE OPTICAL ELEMENTS FOR THE EUV WAVELENGTH RANGE, AND REFLECTIVE OPTICAL ELEMENTS FOR THE EUV WAVELENGTH RANGE

(71) Applicant: Carl Zeiss SMT GmbH, Oberkochen (DE)

(72) Inventor: Vitaliy SHKLOVER, Heidenheim (DE)

(73) Assignee: Carl Zeiss SMT GmbH, Oberkochen (DE)

(21) Appl. No.: 17/981,798

(22) Filed: Nov. 7, 2022

Related U.S. Application Data
(63) Continuation of application No. PCT/EP2021/061915, filed on May 5, 2021.

(30) Foreign Application Priority Data
May 7, 2020 (DE) 10 2020 205 788.5

(51) Int. Cl. G21K 1/06; C03C 17/00

(52) U.S. Cl. CPC G21K 1/062; C03C 17/006; C03C 2217/70; C03C 2218/32; G21K 2201/067

(57) ABSTRACT

Provided for herein are methods for producing reflective optical elements for the EUV wavelength range which have grating structures or which include structures that can serve as phase shifters. The methods may include the following operations: applying a structurable layer to a substrate, applying a reflective coating to the substrate that has been provided with the structurable layer, and locally irradiating the structurable layer. The structurable layer may be irradiated before or after application of the reflective coating.

### CROSS REFERENCE TO RELATED APPLICATIONS

This is a Continuation of International Application PCT/EP2021/061915, which has an international filing date of May 5, 2021, and which claims the priority of German Patent Application 10 2020 205 788.5, filed May 7, 2020. The disclosures of both applications are incorporated in their respective entireties into the present Continuation by reference.

### FIELD

The present disclosure relates to a method of producing reflective optical elements for the EUV wavelength range, including the steps of:
applying a structurable coating to a substrate,
applying a reflective coating to the substrate provided with a structurable coating, with application of at least two layers each of different material as structurable coating, and then locally irradiating the structurable coating under the reflective coating.

The present disclosure also relates to a method of producing reflective optical elements for the EUV wavelength range, comprising the steps of:
applying a structurable coating to a substrate,
locally irradiating the structurable coating and then
applying a reflective coating to the structurable coating, with application of at least two layers each of different material as structurable coating.

The present disclosure also relates to a reflective optical element for the EUV wavelength range that has been produced by the above-described methods, to a reflective optical element for the EUV wavelength range having a substrate and a reflective coating, wherein a structurable coating is disposed between the substrate and the reflective coating, and the structurable coating comprises at least two layers each of different material, and to a reflective optical element for the EUV wavelength range, having a substrate and a reflective coating, wherein a structurable coating is disposed between the substrate and the reflective coating.

### BACKGROUND

Reflective optical elements for the EUV wavelength range (wavelengths in the range from 5 nm to 20 nm) may have structures in order to be able to use them as, for example, phase shift masks or for filtering out or deflecting radiation of unwanted wavelengths. A known method of producing reflective optical elements having lateral structures is, for instance, to use lithographic methods in which a radiation-sensitive layer, also called resist, is effectively exposed to photons, ions or electrons, with transfer of the desired pattern to the radiation-sensitive layer and subsequent structuring thereof by, for example, etching or selective deposition. This structure can be transferred to the reflective optical element. In this way, it is possible to create highly resolved structures in the nanometer range. In this procedure, intensive cleaning processes are necessary, especially for control of particle contamination. Since demands on cleanliness in the case of optical elements for the EUV wavelength range are particularly high, this procedure is very demanding.

DE 10 2012 212 199 A1 discloses irradiating micro- or nanostructured components made of glass, glass ceramic or ceramic with photons or electrons. This leads to material compaction at the irradiated sites. Subsequently, the structured components, for example as substrates for reflective optical elements, may be provided with a reflective coating.

According to DE 10 2011 084 117 A1, a surface form correction of EUV mirrors already provided with a reflective coating is conducted by irradiating them with electrons at an energy that leads to sufficiently high penetration depth that laterally varying compaction is introduced into the substrate, especially when it is made of glass, glass ceramic or ceramic. On account of the low mass of the electrons, interaction with the reflective coating can be neglected.

U.S. Pat. No. 6,844,272 B2, by contrast, proposes, in reflective coatings in the form of multilayer systems, locally influencing the period or total thickness thereof by energy input via irradiation with electrons, photons or ions, preferably by the input of thermal energy in order to locally change the density, which locally influences the optical properties of the multilayer system.

### SUMMARY

The techniques disclosed herein provide for methods of structuring reflective optical elements for the EUV wavelength range, and of providing further structured reflective optical elements for the EUV wavelength range.

The disclosed techniques may be implemented through a method of producing reflective optical elements for the EUV wavelength range, that includes the steps of:
applying a structurable coating to a substrate, with application of at least two layers each of different material as the structurable coating,
applying a reflective coating to the substrate provided with the structurable coating, and then
locally irradiating the structurable coating under the reflective coating after applying the reflective coating,
   wherein the materials mix exothermically and/or react exothermically with one another under the influence of the irradiation.

The disclosed techniques may also be implemented through a method of producing reflective optical elements for the EUV wavelength range, that includes the steps of:
applying a structurable coating to a substrate,
locally irradiating the structurable coating, with application of at least two layers each of different material as the structurable coating, and
applying a reflective coating to the structurable coating after locally irradiating the structurable coating,
   wherein the materials mix exothermically and/or react exothermically with one another under the influence of the irradiation.

The inventors for this application recognized that the application of a structurable coating that includes at least two layers, the two layers each being of a different material, which is structured by local irradiation and is an integral part of the resultant reflective optical element, has advantages. The application of the structurable coating may include applying materials that mix exothermically and/or react exothermically with one another under the influence of the local irradiation, specifically at the locally irradiated sites in the structured layer. This has the advantage that the structurable coating is metastable prior to irradiation. Only when irradiation introduces activation energy is there any mixing or reacting of the materials in which the stable state is formed. In this way, in the production of reflective optical elements by local irradiation, it is possible to introduce permanent structures, whether before or after the application of the reflective coating on the structurable coating. For the structuring, it is possible to work without a resist, such that there is no need for any demanding cleaning steps. The disclosed techniques may also enable introduction of the structures before or after the application of the reflective coating by local irradiation. In particular, by controlled irradiation of the structurable coating, it is possible to avoid any adverse effect on the substrate and/or the reflective coating in the structuring operation, in that, for example, the nature, energy, etc. of the irradiation is chosen appropriately.

More advantageously, the structurable coating is irradiated locally with electrons. It is generally possible without any great complexity to focus and regulate the energy of electron beams as required using commonly known methods and with devices obtainable at relatively low procurement costs. Furthermore, it is possible, even when the reflective coating has already been applied, to irradiate the structurable coating with electrons such that neither the reflective coating nor the substrate is exposed to any significant energy input, and hence the reflective coating and substrate remain unchanged and retain their respective properties. It has been found that it may be particularly advantageous when electrons of energy in the range between 5 keV and 80 keV, preferably 5 keV to 40 keV, and more preferably 10 keV to 25 keV, are used for irradiation. It has likewise been found that it may be advantageous when electron beams with diameters in the range between 5 nm and 1000 μm are used for irradiation. Diameters closer to 1000 μm are, for example, suitable to introduce binary gratings—gratings suitable for bending of undesired radiation in the infrared region out of the beam path. With diameters closer to 5 nm it is possible to introduce, for example, highly resolved structures such as phase shift masks. If irradiation is effected with electrons, preferably at least one of the materials of the layers of the structurable coating has high absorption or low penetration depth for electrons. Such high absorption or low penetration depth may facilitate efficient conversion of the electron energy to activation energy for the triggering of the reaction or the mixing of the layers of the structurable coating. Such high absorption or low penetration depth may also allow for a minimum total thickness of the structurable coating for the desired change in thickness to be achieved via the local irradiation.

Particularly when the reflective coating is applied before the structurable coating is irradiated locally, the layer materials of the structurable coating may be chosen such that, on mixing or reacting under the influence of irradiation, the free Gibbs energy is within a range between −10 kJ/mol and −900 kJ/mol. This can ensure that, in the exothermic mixing or reacting of the layer materials of the structurable coating which is triggered by the irradiation, there is not an excess amount of heat released, which could otherwise damage the substrate material or especially the reflective coating.

Preferably, polishing is conducted on at least one of the layers of the at least two layers of the structurable coating. Such polishing has been found to be advantageous, especially to reduce the surface roughness of the finished reflective optical element in the case of structurable coatings having relatively thick layers, which could otherwise have an adverse effect on reflectivity. The polishing may be conducted either before, during or after the deposition of the at least one layer, in order to reduce any roughening effect. Irrespective of the juncture at which the polishing is performed, any suitable method may be used, including, for example, ion-assisted polishing (see also U.S. Pat. No. 6,441,963 B2; A. Kloidt et al. (1993), “Smoothing of interfaces in ultrathin Mo/Si multilayers by ion bombardment”, Thin Solid Films 228 (1-2), 154 to 157; E. Chason et al. (1993), “Kinetics of Surface Roughening and Smoothing During Ion Sputtering”, MRS Proceedings, 317, 91), plasma-assisted polishing (see also DE 10 2015 119 325 A1), reactive ion-assisted polishing (see also Ping, Study of chemically assisted ion beam etching of GaN using HCl gas, Appl. Phys. Lett. 67 (9) 1995 1250), reactive plasma-assisted polishing (see also U.S. Pat. No. 6,858,537 B2), plasma immersion polishing (see also U.S. Pat. No. 9,190,239 B2), bias plasma-assisted polishing (see also S. Gerke et al. (2015), “Bias-plasma Assisted RF Magnetron Sputter Deposition of Hydrogen-less Amorphous Silicon”, Energy Procedia 84, 105 to 109), polishing via magnetron atomization with pulsed DC current (see also Y. Pei (2009), “Growth of nanocomposite films: From dynamic roughening to dynamic smoothening”, Acta Materialia, 57, 5156-5164), and/or atomic layer polishing (see also U.S. Pat. No. 8,846,146 B2; Keren J. Kanarik, Samantha Tan, and Richard A. Gottscho, Atomic Layer Etching: Rethinking the Art of Etch, The Journal of Physical Chemistry Letters 2018 9 (16), 4814-4821, DOI: 10.1021/acs.jpclett.8b00997).

According to one embodiment, the structurable coating applied is at least two layers, the two layers each being of a different material, wherein the materials mix and/or react with one another under the influence of the local irradiation, resulting in a change in thickness of the structurable coating, specifically at the irradiated site(s), and the layer thicknesses are chosen such that there is no further change in thickness after a desired change in thickness of the structurable coating has been attained. In terms of the process, this procedure has the great advantage that the procedure of structural alteration in the structurable coating on account of the irradiation is self-terminating. This is because the thicknesses of the individual layers of the structurable coating may be chosen such that, after a certain radiation dose, the individual layers have fully mixed or reacted with one another, such that the structuring process cannot continue even if irradiation lasts for longer. In this way, it is possible to achieve precision of structuring that goes beyond control of the irradiation itself, especially of the resultant change in thickness and hence of the surface profile of the reflective optical element produced.

Other aspects of the disclosed techniques relate to a reflective optical element produced as described above, or by a reflective optical element for the EUV wavelength range, having a substrate and a reflective coating, wherein a structurable coating is disposed between the substrate and the reflective coating, and the structurable coating comprises at least two layers, the two layers each being of a different material, wherein the materials of the layers are materials that can react exothermically with one another or mix exothermically. The disclosed techniques also relate to a reflective optical element for the EUV wavelength range, having a substrate and a reflective coating, wherein a structurable coating is disposed between the substrate and the reflective coating, wherein the structurable coating comprises at least two materials that have very low mutual solubility at room temperature and high mutual solubility at temperatures of 300° C. or higher.

The inventor has recognized that providing a structurable coating, especially a structurable coating having the material properties mentioned, which is structured by irradiation and is an integral part of the resultant reflective optical element, has advantages. For example, providing a dedicatedly structurable coating enables the subsequent introduction of structures into a reflective optical element without noticeably adversely affecting the substrate and/or the reflective coating in the structuring operation.

Advantageously, the structurable coating may have lateral variations in thickness. Variations in thickness may be caused by local irradiation of the structurable coating and may lead to a local change in the thickness of the structurable coating, and hence structuring of this layer. These variations in thickness may be introduced such that they impart the effect of a phase shift mask or of a spectral filter, for example in the form of a diffraction grating, to the reflective optical element. The variations in thickness may correlate, inter alia, with structural and/or stoichiometric differences between the materials at the sites of different density.

According to specific embodiments, the structurable coating may include at least one material of a density of 12 g/cm³ or more, preferably 15 g/cm³ or more, and more preferably 18 g/cm³. It is known that penetration depth into the material on irradiation with photons, ions and especially electrons is inversely proportional to the density of the material. By using materials with such densities enables prevention of penetration of the local irradiation through the structurable coating into the substrate of the reflective optical element. By preventing penetration into the substrate, unwanted compaction of the substrate material may be avoided, and may also enable the structurable coating to be kept very thin to avoid or reduce adverse effects such as high layer stress or excessive roughening.

Preferably, the structurable coating includes at least two layers, the two layers each being of a different material. More preferably, the structurable coating has a multitude of layers of at least two materials in an alternating arrangement. This construction of the structurable coating enables introduction of a structure into the structurable coating by providing activation energy to the at least two materials through irradiation, so as to trigger mixing or reaction of the at least two materials at the surfaces where they adjoin one another. By providing a multitude of layers, the number of interfaces at which these processes can take place is increased. Preferably, the materials of the layers are materials that can react exothermically with one another or mix exothermically. This has the advantage that the structurable coating is metastable. For example, only when irradiation introduces activation energy is there any mixing or reacting of the materials in which the stable state is formed. In this way, it is possible to introduce permanent structures into reflective optical elements by local introduction of activation energy into the structurable coating. As noted above, the permanent structures may be configured to provide, for example, a phase shift or a wavelength filtering to the EUV radiation reflected by the optical element. Advantageously, the layer materials are chosen such that, on mixing or reacting on introduction of activation energy into the structurable coating, for example by irradiation, the free Gibbs energy is within a range between −10 kJ/mol and −900 kJ/mol. This can ensure that not too much heat is released, which could otherwise damage the substrate material or the reflective coating in particular.

Advantageously, the structurable coating includes one or more of the following materials: tungsten, rhenium, osmium, iridium, tantalum, hafnium, ruthenium, platinum, gold, alloys thereof, oxides thereof, carbides thereof, nitrides thereof and borides thereof. First, use of these materials may permit reduction or minimization of the thickness of the structurable coating, in order to avoid any additional layer stresses, as far as possible. Second, use of these materials may reduce or avoid penetration of EUV radiation into the substrate in operation of the reflective optical element, which can lead to damage to the substrate on account of high absorption of EUV radiation by the materials mentioned. In particular, the structurable coating may include, for example, metallic and ceramic materials.

The structurable coating in the variant described above preferably includes at least one further material from the group consisting of carbon, boron, silicon, boron carbide and boron nitride. These materials, after supply of activation energy by irradiation, can react efficiently, especially with materials from the group consisting of tungsten, rhenium, osmium, iridium, tantalum, hafnium, ruthenium, platinum, and gold, forming compounds having a distinctly different density than the respective starting materials, which allows structures having different thickness to be introduced in the structured layer by local irradiation, or they may already have been introduced.

In one specific embodiment, the structurable coating includes at least two materials that have very low mutual solubility at room temperature and high mutual solubility at temperatures of 300° C. or higher. More preferably, these two materials are applied alternately, each in the form of a multitude of layers. A structurable coating composed of at least two materials having such different solubility is in a metastable state at room temperature. If the structurable coating is locally heated to a sufficiently high temperature through energy input by irradiation, mixing of these materials may take place, which may lead to a change in density. This change in density may lead to a structuring of the structurable coating. More preferably, in these variants, the structurable coating includes a first material from the group consisting of tungsten, tantalum and indium, and a second material from the group consisting of vanadium, titanium, rhodium, platinum and chromium.

### BRIEF DESCRIPTION OF THE DRAWINGS

The techniques disclosed herein are to be elucidated in detail with reference to a working examples described with reference to FIGS. 1-6. The figures show:

FIG. 1: a diagram of a first execution variant of a reflective optical element with a structurable coating;

FIG. 2: a diagram of a second execution variant of a reflective optical element with a structurable coating;

FIG. 3: a diagram of a third execution variant of a reflective optical element with a structurable coating in a first state;

FIG. 4: a diagram of the third execution variant of a reflective optical element with a structurable coating in a second state;

FIG. 5: a schematic flow diagram of a first proposed method of producing a reflective optical element; and

FIG. 6: a schematic flow diagram of a second proposed method of producing a reflective optical element.

### DETAILED DESCRIPTION

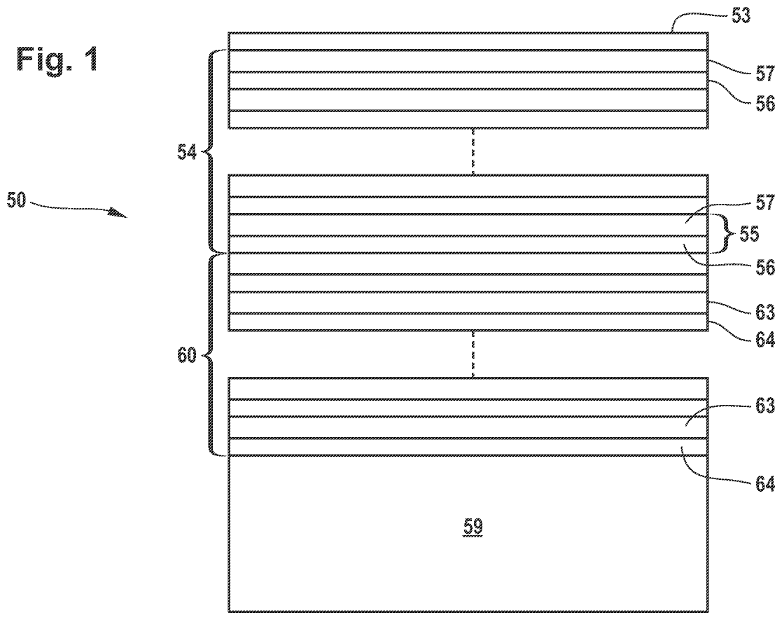

FIG. 1 illustrates a schematic of the construction of a reflective optical element 50 having, on a substrate 59, a structurable coating 60 and a reflective coating 54. Reflective coating 54 has, in the present embodiment, layers applied in an alternating manner. The layers of reflective coating 54 are of a material having a relatively high real part of the refractive index at the operating wavelength at which a, for example, lithographic exposure is conducted (also called spacer 56), and a material having a relatively low real part of the refractive index of the operating wavelength (also called absorber 57), with an absorber-spacer pair forming a stack 55. In a sense, this simulates a crystal, the lattice planes of which correspond to the absorber layers at which Bragg reflection takes place. Typically, reflective optical elements for an EUV lithography apparatus or an optical system are designed such that the respective wavelength of maximum reflectivity substantially coincides with the working wavelength of the lithography process or other applications of the optical system.

The thicknesses of the individual layers 56, 57 and also of the repeating stacks 55 may be constant over the entire multilayer system 54 or vary over the area or the total thickness of the multilayer system 54, depending on what spectral or angle-dependent reflection profile or what maximum reflectivity at the operating wavelength is to be achieved. When the layer thicknesses over the entire multilayer system 54 are essentially constant, reference is also made to a period 55 rather than a stack 55. The reflection profile may also be influenced in a targeted manner by supplementing the basic structure composed of absorber 57 and spacer 56 using additional materials that are more and less absorbent. The use of such additional materials may increase the possible maximum reflectivity at the respective working wavelength. To that end, absorber and/or spacer materials in some stacks can be mutually interchanged, or the stacks can be constructed from more than one absorber and/or spacer material. Furthermore, it is also possible to provide additional layers as diffusion barriers between spacer and absorber layers 56, 57. A material combination that is customary for, for example, an operating wavelength of 13.4 nm is molybdenum as the absorber material and silicon as the spacer material. A period 55 for such an operating wavelength may be a thickness of approximately 6.7 nm, with the spacer layer 56 usually being thicker than the absorber layer 57. Further typical material combinations are, among others, silicon-ruthenium or molybdenum-beryllium. In addition, a protective layer 53, possibly also of multilayer design, can be provided on the multilayer system 54.

Typical substrate materials for reflective optical elements for EUV lithography are silicon, silicon carbide, silicon-infiltrated silicon carbide, quartz glass, titanium-doped quartz glass, glass and glass ceramic. Especially in the case of such substrate materials, it is additionally possible to provide a layer between reflective coating 54 and substrate 59 which is composed of a material having high absorption for radiation in the EUV wavelength range which is used in the operation of the reflective optical element 50 in order to protect the substrate 59 from radiation damage, for example unwanted compaction. Furthermore, the substrate can also be composed of copper, aluminum, a copper alloy, an aluminum alloy or a copper-aluminum alloy.

The structurable coating 60 may include at least two layers, each of the two layers being of a different material. It may preferably include a multitude of layers of at least two materials in an alternating arrangement. In the example shown in FIG. 1, the structurable coating 60 has a multitude of layers 63, 64 composed of—without restriction of generality—two different materials in an alternating arrangement. More preferably, these are materials that can react exothermically with one another or mix exothermically. Such material combinations form a structurable coating 60 in an initially metastable state. If a certain amount of energy is introduced into the structurable coating that is sufficient to serve as activation energy, these two materials can react with one another in order to form one or more other materials, or they mix with one another or go into solution together. Thereafter, the structurable coating 60 is in a more stable state than before at the points at which the activation energy was introduced. The change in the structurable coating 60 that has been effected by the activation energy is associated with greater or lesser changes in density, such that permanent structures, such as binary gratings or phase shifters, inter alia, may be introduced in this way into the reflective optical element 50. In order not to induce excessively large layer stresses, the structurable coating 60 should advantageously not be too thick.

The more layers 63, 64 that are provided, the more interfaces there are at which a reaction or mixing can take place. Advantageously, at least one of the materials chosen has high absorption for the irradiation used to introduce the activation energy, in order to: first be able to sufficiently convert the irradiation energy to activation energy, and second to be able to protect the substrate 59 from damage by the structuring irradiation. Such high absorption may additionally or alternatively provide high absorption for the EUV radiation used in operation of the reflective optical element 50 in order to protect the substrate 59 from corresponding radiation damage. For protection of the substrate 59 from the structuring irradiation, and if appropriate additionally against the EUV radiation in operation, it is also possible to provide an additional layer between structurable coating 60 and substrate 59. If structuring is accomplished by irradiation with electrons, it may be possible to, for example, provide a layer comprising a metal having high electron absorption. Purely by way of example, for electrons of energy 10 keV, for instance, it may be possible to provide a structurable coating 60 having tungsten layers 63 or 64 and a total thickness of about 300 nm, and for electrons of energy about 20 keV, a total thickness of about 600 nm.

It is optionally possible to provide a dedicatedly polishable layer between the structurable coating 60 and the reflective coating 54, in order that any roughening of the structurable coating 60 does not continue into the reflective coating 54 and the reflectivity of the reflective optical element 50 is not reduced. In further variants, the structurable coating 60 may be formed from two or more subsections each composed of at least one layer, with a polishable layer disposed between every two subsections. Any appropriate polishing method may be used without deviating from the disclosed techniques, including, for example, ion-assisted polishing, plasma-assisted polishing, reactive ion-assisted polishing, reactive plasma-assisted polishing, plasma immersion polishing, bias plasma-assisted polishing, polishing via magnetron atomization with pulsed DC current, and/or atomic layer polishing.

Alternatively or additionally, polishing may be conducted on at least one or more, or optionally even on all, of layers 63, 64 of the structurable coating. This has been found to be advantageous to reduce the surface roughness of the finished reflective optical element, especially in the case of structurable coatings having relatively thick layers, which could otherwise have an adverse effect on reflectivity. The polishing may be conducted either before, during or after the deposition of the at least one layer, in order to reduce any roughening effect. Irrespective of the juncture at which the polishing is conducted, any suitable polishing method may be used, including, for example, ion-assisted polishing, plasma-assisted polishing, reactive ion-assisted polishing, reactive plasma-assisted polishing, plasma immersion polishing, bias plasma-assisted polishing, polishing via magnetron atomization with pulsed DC current, and/or atomic layer polishing.

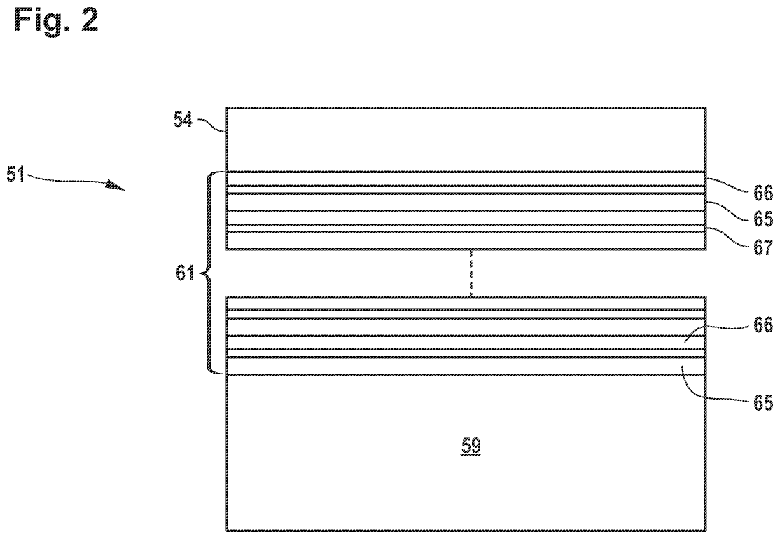

In the working example of reflective optical element 51 shown in FIG. 2, the structurable coating 61 disposed between the substrate 59 and the reflective coating 54, which may be configured as already elucidated in conjunction with FIG. 1, has a multitude of layers 65, 66, 67 composed of three different materials, which are arranged in repeating stacks. The third material may likewise be a material that reacts or mixes exothermically with the two other materials. It is alternatively possible to provide a material that reduces or even compensates entirely for stresses that are caused by the reflective coating 54 and the structurable coating 61. In particular, the materials and the number of layers and the thicknesses of at least one of the layers 65, 66, 67 may be optimized with regard to compensation of the stress caused by the reflective coating 54. In addition, it is also possible to take all other known measures for compensation or reduction of stress, for instance symmetric coating of the reverse side of the substrate 59, the provision of an additional layer between substrate 59 and structurable coating 61 or between structurable coating 61 and reflective coating 54, where this layer may also have a multilayer structure. Alternatively, the material of the structurable coating 61 or of any layers forming the structurable coating 61 may also be chosen such that the overall layer stress both before and after the structuring by local irradiation is at a minimum, and the layer stress of the structurable coating 61 opposes the layer stress caused by the reflective coating 54. Layer stress may also be influenced by the coating parameters. A reduction in overall layer stress can reduce the risk of layer detachment. It has also been found to be helpful to choose, as layer material for the structurable coating 61, at least one material that can adapt plastically thereto in the event of a deformation resulting from the structuring and/or layer stress. A measure to counter the detachment of the structurable coating 61 and the substrate 59 may involve providing an adhesion promoter layer therebetween.

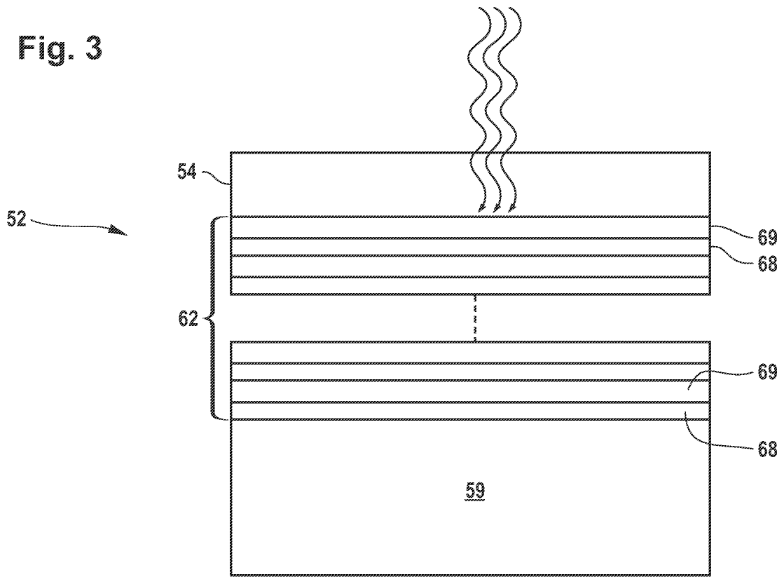

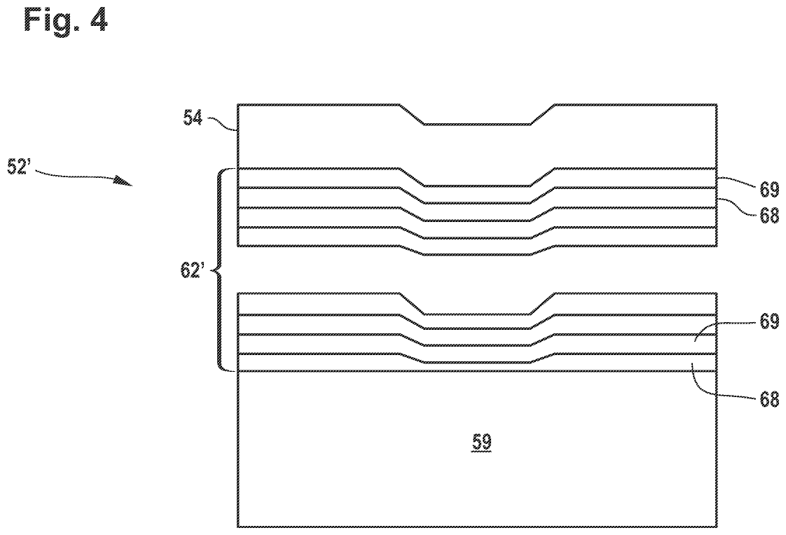

FIGS. 3 and 4 show a third working example of a reflective optical element 52, 52′ for the EUV wavelength range at the start of local irradiation (FIG. 3) and after conclusion of local irradiation (FIG. 4). In the reflective optical element 52, 52′, analogously to the example shown in FIG. 1, a structurable coating 62, 62′ is disposed between the substrate 59 and the reflective coating 54. Also analogously to the example from FIG. 1, structurable coating 62, 62′ includes a multitude of layers 68, 69 of two different materials. Layers 68, 69 are alternately arranged and their respective materials mix exothermically and/or react exothermically with one another under the influence of activation energy, for instance via irradiation. It has been found to be advantageous when the layer materials are chosen such that, on mixing or reacting under the influence of irradiation, the free Gibbs energy is within a range between −10 kJ/mol and −900 kJ/mol. On the one hand, the evolution of heat is low enough to damage neither the substrate nor any reflective coating already present. On the other hand, the state of the structurable coating 62, 62′ after the reaction or the mixing is noticeably more stable than in the original state.

In order to introduce the activation energy needed to trigger the reaction or the mixing of the materials of structurable coating 62, in the example presented here, it is irradiated with electrons (symbolized by the wavy arrows). This has the advantage that both the electrical energy and the diameter of the electron beam can be adjusted very accurately over a wide range. For instance, it has been found to be useful to irradiate with electrons within an energy range between 5 keV and 80 keV, preferably 5 keV to 40 keV, and more preferably 10 keV to 25 keV, in order to: first penetrate through the reflective coating and to impair it as little as possible, and second not to damage the substrate. In relation to the diameter of the electron beam, although it is also possible to work with two or more electron beams successively or in parallel, preference is given to working with diameters in the range between 5 nm and 1000 μm. Diameters closer to 1000 μm, for example, may be suitable to introduce binary gratings, for instance, for bending undesirable radiation in the infrared region out of the beam path. With diameters closer to 5 nm, it is possible to introduce, for example, highly resolved structures that act as phase shift masks.

A local change in the thickness of the structurable coating caused by the local irradiation of the structurable coating may cause the structuring of this layer. The variations in thickness may correlate inter alia with structural and/or stoichiometric differences between the materials at the sites of different density. In the example shown in FIG. 4, the irradiation with electrons has a compacting effect, such that a depression has formed beneath the reflective coating 54 at the irradiated site. Depending on the size of the path difference for an EUV ray reflected in the use of the reflective optical element 52′ at sites with depressions compared to sites without depressions, there may be, for example, a phase shift in the case of relatively small values. In the case of larger structures, any undesired radiation of higher wavelength present in the EUV beam, for instance, may be bent out of the beam path.

In the examples shown in FIGS. 3 and 4, the structurable coating 62, 62′ has at least one layer of a material of density 12 g/cm³ or more, preferably 15 g/cm³ or more, or more preferably 18 g/cm³, in order to limit the penetration depth of the irradiation as far as possible into the structurable 62, 62′ coating and to prevent any adverse effect on the substrate material.

In a first preferred variant, the materials of layers 68, 69 are chosen such that they have very low mutual solubility at room temperature and high mutual solubility at temperatures of 300° C. or higher. In this variant, the structurable coating 62 is in a metastable state at room temperature. If it is heated to a sufficiently high temperature locally by energy input by irradiation, mixing of these materials can take place, which can lead to a change in density and hence structuring. More preferably, in these variants, the structurable coating 62, 62′ comprises a first material from the group consisting of tungsten, tantalum and iridium, and comprises a further material from the group consisting of vanadium, titanium, rhodium, platinum and chromium.

In a further preferred variant, the structurable coating 62, 62′ includes one or more of the materials from the group consisting of tungsten, rhenium, osmium, iridium, tantalum, hafnium, ruthenium, platinum, gold, alloys thereof, oxides thereof, carbides thereof, nitrides thereof and borides thereof. These materials have the advantage that they can protect the substrate from radiation damage in operation of the reflective optical element 52,52′ with EUV radiation. They also have a high absorption for electrons, such that the electron energy can be converted particularly efficiently to activation energy. Owing to these properties, the total thickness of the structurable coating 62, 62′ can be kept lower than in the case of materials having lower absorption for electrons and EUV radiation, such that any layer stress that occurs can be minimized in a simpler manner. In particular, it has been found to be useful for exothermic reactions when the structurable coating 62, 62′ includes at least one further material from the group consisting of carbon, boron, silicon, boron carbide and boron nitride. Boron carbide and boron nitride may also be applied in non-stoichiometric ratios as BₓC_{y} or BₓN_{z}, in order that the individual elements boron, carbon and nitrogen can react efficiently, especially with the aforementioned metals. Carbon layers can preferably be applied as amorphous or as diamond-like layers.

It should be pointed out that layers of tantalum, platinum and titanium, in particular, have the property of plastic adaptability to deformations. If the structurable coating should conclude on the substrate side with a layer of chromium, tantalum, niobium, molybdenum, titanium, or one of their alloys or compounds, and the substrate should be composed of silicon, silicon carbide, silicon-infiltrated silicon carbide, quartz glass, titanium-doped quartz glass, glass and glass ceramic, an adhesion promoter layer between the structurable coating and the substrate may have a particularly good adhesion effect.

The following list is a non-exhaustive list of illustrative possible material combinations:

| Starting materials | Final material(s) | Free Gibbs energy | |
|---|---|---|---|
| W + C | WC | −38.3 | kJ/mol |
| W + 2 Si | WSi2 | −90.9 | kJ/mol |
| Re + 2 Si | ReSi2 | −90.3 | kJ/mol |
| Hf + 2 B | HfB2 | −332 | kJ/mol |
| Hf + C | HfC | −249 | kJ/mol |
| 3 Hf + B4C | 2 HfB2 + HfC | −851 | kJ/mol |
| TaB2 + Hf | HfB2 + Ta | −126 | kJ/mol |
| WC + Ta | TaC + W | −104 | kJ/mol |
| RuO2 + Hf | Ru + HfO2 | −836 | kJ/mol |
| RuO2 + Re | ReO2 + Ru | −138 | kJ/mol |
| SiO2 + Hf | HfO2 + Si | −232 | kJ/mol |
| TaB2 + HfC | TaC + HfB2 | −19.7 | kJ/mol |

An estimate of the change in thickness resulting from radiation is elucidated by the example that follows with reference to a structurable coating that includes a multitude of layers of tungsten and silicon. The density and molar mass of the tungsten and silicon starting materials may be used to calculate the molar volume of each. Proceeding from a density of 19.25 g/cm³ and a molar mass of 183.84 for tungsten and a density of 2.336 g/cm³ and a molar mass of 2.09 g/mol for silicon, a molar volume of 9.47 cm³/mol is found for tungsten and of 12.06 cm³/mol for silicon. For tungsten silicide which is formed by irradiation-induced reaction, a density of 9.3 g/cm³ and a molar mass of 240.01 g/mol give a molar volume of 25.81 g/mol. Taking into account that the molar ratio of tungsten to silicon should be 1:2 in the structurable coating, the shrinkage of the structurable coating as a result of the radiation, if it is fully converted to tungsten silicide at the irradiated sites, is about 23%. This means that the structurable coating should have a total thickness of 4.2 nm if the aim is to lower it by 1 nm. This procedure can be applied correspondingly to any desired material combination.

It has been found to be particularly advantageous, in order to have particularly good control over changes in layer thickness within the structurable coating, when the layer thicknesses are chosen such that there is no further change in thickness after attainment of a desired change in thickness of the structurable coating. In other words, the thicknesses of the individual layers of the structurable coating should then be chosen such that, after a certain radiation dose, the individual layers have fully mixed or reacted with one another, such that the structuring process cannot continue even if irradiation lasts for longer, i.e., the structuring process is self-terminating.

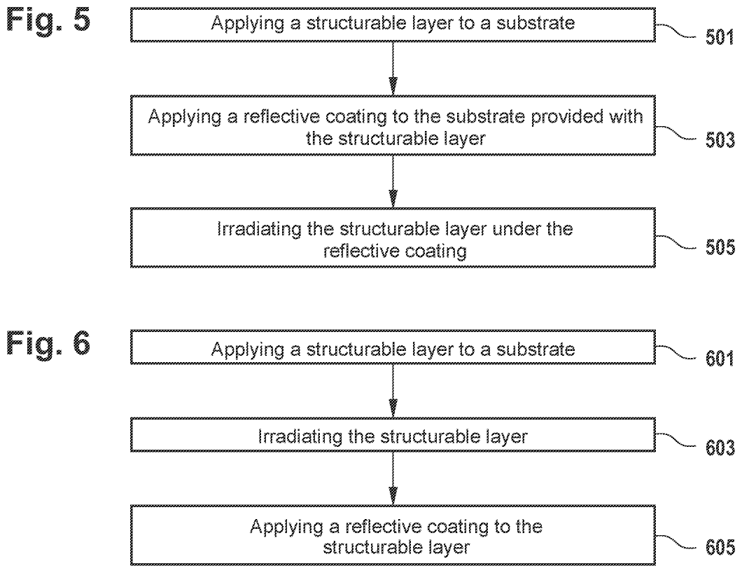

FIGS. 5 and 6 show, in schematic form, the sequence of two options by which the above-described reflective optical elements for the EUV wavelength range may be produced according to the disclosed techniques. The sequence shown in FIG. 5 corresponds to the procedure that has been elucidated in connection with the preceding examples. In a first step 501, a structurable coating is first applied to a substrate, then, in a step 503, a reflective coating is applied to the substrate provided with the structurable coating, such that the structurable coating is disposed between substrate and reflective coating. Thereafter, in a step 505, the structurable coating disposed beneath the reflective coating is irradiated in order to structure it.

By contrast, in the example shown in FIG. 6, after a structurable coating has been applied to a substrate in a step 601, this structurable coating is irradiated for structuring purposes in a further step 603, before a reflective coating is applied to the structurable and effectively already structured layer in a step 605. A further option, not shown here, is to perform a first partial structuring by irradiation of the structurable coating prior to the application of the reflective coating thereto, and a further partial structuring via a further irradiation after the reflective coating has been applied.

Both in the variant shown in FIG. 5 and in the variant shown in FIG. 6, the structurable coating applied may be at least two layers, each of different material. The materials of the layers may be materials that can react exothermically with one another or mix exothermically. The structurable coating applied may also comprise at least two materials that have very low mutual solubility at room temperature and high mutual solubility at temperatures of 300° C. or higher. These materials may advantageously be applied as at least two layers each of different material, in order to form the structurable coating.

In a modification of these procedures, for instance via different irradiation parameters such as energy, dose, mode of irradiation and/or corresponding design of the structurable coating by division into two or more substacks and variation of layer material and thickness, the structuring may be performed by local irradiation in two or more component steps, in which the structuring is conducted first in the region of the structurable coating remote from the substrate, and the structuring is conducted ever closer to the substrate in the subsequent irradiation step(s) by working at different penetration depths.

The above elucidations relating to the procedure in the production of the proposed reflective optical elements and especially in the irradiation of the structurable coating for structuring purposes are applicable analogously to the two latter options as well.

It should be pointed out that, in the production of reflective optical elements having a structurable coating having at least two layers each of different material, reflectivity can be increased by polishing one of the layers, preferably two or more or even all layers of the structurable coating, by irradiation with ions in the coating operation or after the application of the respective layer and before the next layer is applied thereto. Too high a surface roughness can otherwise lead to poorer reflectivity than would be expected on the basis of the construction of the reflective coating. A particularly positive effect has been observed in the case of silicon layers.

The reflective optical elements for the EUV wavelength range that are proposed here may be used as EUV mirrors, for example in EUV lithography devices or in mask or wafer inspection systems. In EUV lithography devices, they may also be used as masks.

If necessary, these reflective optical elements may be repaired by measuring the surface profile of the reflective coating and comparing it with a target profile and, if there are one or more sites in the surface profile having a variance from the target profile, irradiating the substrate and/or the structurable coating at this/these sites. By local irradiation of the substrate and the structurable coating, it is possible to introduce a change in thickness at that location, especially by a change in density, the effect of which can be that the variance of the actual surface profile from the target profile becomes less at that location. Advantageously, electron irradiation is also employed for the repair, it being possible to use electrons of higher energy than in the structuring already affected in order to be able to achieve higher penetration depth and hence a local change in density in deeper regions.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

### REFERENCE SIGNS

50 Reflective optical element
51 Reflective optical element
52, 52′ Reflective optical element
53 Protective layer
54, 54′ Reflective coating
55 Stack
56 Absorber
57 Spacer
59 Substrate
60 Structurable coating
61 Structurable coating
62, 62′ Structurable coating
63 First layer
64 Second layer
65 First layer
66 Second layer
67 Third layer
68 First layer
69 Second layer
501 Method step
503 Method step
505 Method step
601 Method step
603 Method step
605 Method step

What is claimed is:

1. A method of producing reflective optical elements for an EUV wavelength range, comprising the steps of:
applying a structurable coating to a substrate, wherein the structurable coating comprises at least two layers of different materials;
applying a reflective coating to the substrate provided with the structurable coating; and
locally irradiating the structurable coating,
wherein the different materials of the structurable coating mix exothermically and/or react exothermically with one another under influence of the irradiating, thereby introducing permanent structures by local irradiation.

2. The method of claim 1, wherein locally irradiating the structurable coating is performed prior to applying the reflective coating.

3. The method of claim 1, wherein locally irradiating the structurable coating is performed after applying the reflective coating.

4. The method of claim 1, wherein locally irradiating the structurable coating comprises locally irradiating the structurable coating with electrons.

5. The method of claim 1, wherein the different materials are chosen such that, on mixing or reacting under the influence of local irradiation, the free Gibbs energy is within a range between −10 kJ/mol and −900 kJ/mol.

6. The method of claim 1, further comprising polishing at least one layer of the at least two layers of the structurable coating.

7. The method of claim 1, wherein the different materials mix and/or react with one another under the influence of the local irradiation, resulting in a change in thickness of the structurable coating, and wherein layer thicknesses of the at least two layers are chosen such that there is no further change in thickness after the change in thickness of the structurable coating has been attained.

8. A reflective optical element produced by the method of claim 1.

9. A reflective optical element for an EUV wavelength range, comprising:
a substrate;
a reflective coating; and
a structurable coating, wherein the structurable coating comprises a multilayer system disposed between the substrate and the reflective coating, and the structurable coating comprises at least two layers each of different materials, wherein the different materials of the at least two layers react exothermically with one another or mix exothermically.

10. The reflective optical element of claim 9, wherein the at least two layers have low mutual solubility at room temperature and high mutual solubility at temperatures of 300° C. or higher.

11. The reflective optical element of claim 9, wherein the structurable coating has lateral variations in thickness.

12. The reflective optical element of claim 9, wherein the structurable coating comprises at least one material having a density of 12 g/cm³ or more.

13. The reflective optical element of claim 9, wherein the structurable coating comprises at least two layers of each of the different materials.

14. The reflective optical element of claim 9, wherein the structurable coating comprises a multitude of layers of the different materials arranged in alternation.

15. The reflective optical element of claim 9, wherein the structurable coating comprises materials from the group consisting of tungsten, rhenium, osmium, iridium, tantalum, hafnium, ruthenium, platinum, gold, alloys thereof, oxides thereof, carbides thereof, nitrides thereof and borides thereof.

16. The reflective optical element of claim 15, wherein the structurable coating comprises a further material from the group consisting of carbon, boron, silicon, boron carbide and boron nitride.

17. The reflective optical element of claim 9, wherein the structurable coating comprises a first material from the group consisting of tungsten, tantalum and indium, and comprises a second material from the group consisting of vanadium, titanium, rhodium, platinum and chromium.
